(19) United States
(12) Patent Application Publication
(10) Pub. No.: US 2026/0239582 A1
(43) Pub. Date: Aug. 13, 2026

(54) ELECTRONIC ASSEMBLY, NOTABLY CONFIGURED TO BE INTEGRATED IN AN INVERTER

(71) Applicant: Valeo eAutomotive Germany GmbH, Erlangen (DE)

(72) Inventors: Romain HENNEGUET, Etaples-sur-Mer (FR); Vivek THANGARAJAN, Chennai (IN); Belber MARSHAL, Chennai (IN)

(73) Assignee: Valeo eAutomotive Germany GmbH, Erlangen (DE)

(21) Appl. No.: 19/536,759

(22) Filed: Feb. 11, 2026

(30) Foreign Application Priority Data
Feb. 11, 2025 (FR) FR2501428

(51) Int. Cl. H05K 7/20; H10W 40/73

(52) U.S. Cl. CPC H05K 7/209; H05K 7/20254; H05K 7/20272; H05K 7/2039; H05K 7/20781; H05K 7/20927; H10W 40/73

(57) ABSTRACT

An electronic assembly includes a first cooling device having a first thermal contact face, a second cooling device having a second thermal contact face and a bearing face, at least one power electronics module, a retention structure having at least one elastic portion, and a plurality of attachment elements. The plurality of attachment elements exerts a force on the retention structure, giving rise to clamping loads on the bearing face of the second cooling device, these clamping loads being sufficient to rigidly secure together the first cooling device, the second cooling device and the retention structure.

### FIELD OF THE INVENTION

The present invention relates in particular to an electronic assembly, notably configured to be integrated in an inverter.

### PRIOR ART

Patent application WO2022248427 discloses a cooling structure comprising stacked structures forming a network of openings and chambers for the flow of a cooling fluid. This structure is placed in a pipe and this pipe is closed by a base structure of a power electronics module. The cooling liquid flows through the meanderings within this structure.

The invention aims to provide a new type of thermal regulation device.

### SUMMARY OF THE INVENTION

The invention relates to an electronic assembly comprising:
a first cooling device comprising a first thermal contact face,
a second cooling device comprising a second thermal contact face and a bearing face,
at least one power electronics module having a first face and a second face, in particular parallel to one another, the first face of the power electronics module being in thermal contact with the first thermal contact face of the first cooling device and the second face of the power electronics module being in thermal contact with the second thermal contact face of the second cooling device,
a retention structure placed in contact with the bearing face of the second cooling device, and comprising at least one elastic portion,
a plurality of attachment elements, characterized in that:
   the first cooling device and the elastic portion of the retention structure each comprise a plurality of attachment holes,
   the plurality of attachment elements passes through the attachment holes and exerts a force on the retention structure, causing deformation of the elastic portions of the retention structure, this deformation giving rise to clamping loads on the bearing face of the second cooling device, these clamping loads being sufficient to rigidly secure together the first cooling device, the second cooling device and the retention structure.

Advantageously, the invention makes it possible to reduce the distance between the cooling devices and the power electronics module.

Advantageously, the use of a retention structure comprising an elastic portion makes it possible to put together the electronic assembly as an autonomous assembly, without the need for attachment to a support part.

This allows the electronic assembly to be put together in one piece before it is attached to other components.

According to one aspect of the invention, the retention structure comprises a retention face arranged to be placed in contact with the bearing face of the second cooling device.

According to one aspect of the invention, the retention structure comprises a plurality of elastic portions.

According to one aspect of the invention, the retention structure comprises a plurality of wings forming elastic portions of the retention structure, and extending from the retention face of the retention structure.

According to one aspect of the invention, the wings extend on either side of the second cooling device, and are not in contact with the second cooling device.

According to one aspect of the invention, the retention structure comprises a plurality of retention tabs.

According to one aspect of the invention, the retention tabs comprise a flat portion forming part of the retention face of the retention structure, and a bent portion arranged to come into contact with a lateral face of the second cooling device in such a way as to hold the second cooling device in position laterally.

Lateral face of the second cooling device refers to the faces of the second cooling device that are substantially perpendicular to the bearing face of the second cooling device.

According to one aspect of the invention, the retention structure comprises at least two retention tabs placed in contact with opposite lateral faces of the second cooling device.

According to one aspect of the invention, the retention structure is made of metal, notably aluminium.

According to one aspect in the invention, the first cooling device comprises a first circulation channel for a heat transfer fluid.

According to one aspect in the invention, the second cooling device comprises a second circulation channel for a heat transfer fluid.

According to one aspect to the invention, the first circulation channel and/or the second circulation channel for heat transfer fluid have a substantially rectangular section.

According to one aspect of the invention, the power electronics module or modules are sandwiched between the first cooling device and the second cooling device.

Advantageously, the invention thus makes it possible to cool the power electronics module on both faces, thus making it possible to discharge a greater amount of heat.

Advantageously, since the first cooling device and the second cooling device have heat transfer fluid circulating through them, they make it possible to discharge more efficiently the heat released by the power electronics module when it is in operation.

According to one aspect of the invention, the first cooling device and the second cooling device each comprise plates configured to form at least one circulation channel for a heat transfer fluid, one of the plates defining the first thermal contact face and the second thermal contact face, respectively.

In this case, the first cooling device and the second cooling device have a similar structure, with a heat transfer fluid channel formed by plates.

According to one aspect of the invention, the heat transfer fluid circulation channel of the first cooling device and/or the second cooling device has a generally rectilinear shape.

According to one aspect of the invention, the first cooling device and the second cooling device are made of metal, for example aluminium.

According to one aspect of the invention, a thermal interface material (for example a gap filler or thermal paste or thermal grease or a film) is present between the first face of the power electronics module and the first thermal contact face of the first cooling device.

According to one aspect of the invention, such a thermal interface material is also present between the second face of the power electronics module and the second thermal contact face of the second cooling device.

According to one aspect of the invention, the electronic assembly comprises a plurality of power electronics modules, for example two or three power electronics modules, notably arranged in a row, and sandwiched between the first cooling device and the second cooling device.

According to one aspect of the invention, the electronic assembly comprises a positioning support arranged to receive the power electronics module or modules and to allow relative positioning between the power electronics module, the first cooling device and the second cooling device when the electronic assembly is being put together.

According to one aspect of the invention, the positioning support takes the form of a frame, and comprises a plurality of positioning openings, in particular as many positioning openings as there are power electronics modules, each positioning opening being arranged to accommodate a power electronics module.

In particular, the positioning support comprises three positioning openings.

According to one aspect of the invention, the positioning support comprises an upper face and a lower face.

According to one aspect of the invention, the upper face of the positioning support is placed in contact with the first cooling device, and comprises positioning reliefs making it possible to position the first cooling device on the positioning support.

According to one aspect of the invention, the lower face of the positioning support is placed in contact with the second cooling device, and comprises positioning reliefs making it possible to position the second cooling device on the positioning support.

According to one aspect of the invention, the positioning support is sandwiched between the first cooling device and the second cooling device, and forms a stack with the first cooling device and the second cooling device.

According to one aspect of the invention, the positioning support is made of metal or plastic.

According to one aspect of the invention, the attachment elements are screws.

According to one aspect of the invention, the attachment elements:
exert a force on the retention structure,
exert an opposite force on the first cooling device.

According to one aspect of the invention, the attachment elements are attached directly to the first cooling device, and apply a force directly on the first cooling device.

For example, the attachment elements are screws screwed directly into an attachment hole in the first cooling device.

According to another embodiment of the invention, the attachment elements are attached to intermediate parts placed bearing on the second cooling device, and exerting the opposite force on the first cooling device.

For example, the attachment elements are screws screwed onto nuts placed bearing on the first cooling device.

According to one aspect of the invention, the electronic assembly comprises a plurality of adjustment rings.

According to one aspect of the invention, the adjustment rings have a tubular shape, and are placed around the attachment elements of the electronic assembly.

According to one aspect of the invention, the adjustment rings comprise an upper face and a lower face.

According to one aspect of the invention, the lower face of the adjustment rings is placed in contact with a flat surface of the positioning support and/or of the first cooling device.

According to one aspect of the invention, the upper face of the adjustment rings is parallel to the retention structure, and is placed facing an elastic area of the retention structure such that:
when the retention structure is placed, without deformation, in contact with the second cooling device, the upper face of the adjustment rings is located at a distance D from the retention structure,
when the retention structure is deformed by the force exerted by the attachment elements, the elastic parts of the retention structure are in contact with the upper face of the adjustment rings.

Advantageously, the height of the adjustment rings makes it possible to adjust the distance D between the retention structure and the upper face of the adjustment rings, and thus adjust the maximum deformation of the elastic parts of the retention structure.

According to one aspect of the invention, the adjustment of the height of the adjustment rings makes it possible to adjust the vertical loads generated on the bearing face of the second cooling device by the retention structure.

The electronic assembly is notably configured to be integrated in an inverter. The invention also relates to an inverter comprising an electronic assembly as described above.

### LIST OF FIGURES

Other features, details and advantages of the invention will become more clearly apparent from reading the following description and from several examples of embodiments given by way of non-limiting indication with reference to the appended schematic drawings, in which:

FIG. 1 is a perspective view of an electronic assembly according to the invention.

FIG. 2 is a view in cross section of an electronic assembly according to the invention, before clamping of the attachment elements.

The features, variants and different embodiments of the invention may be combined with one another, in various combinations, provided that they are not mutually exclusive or incompatible. It will be possible, in particular, to imagine variants of the invention that comprise only a selection of the features described below, in isolation from the other features described, provided that this selection of features is sufficient to confer a technical advantage and/or to distinguish the invention from the prior art.

### DETAILED DESCRIPTION

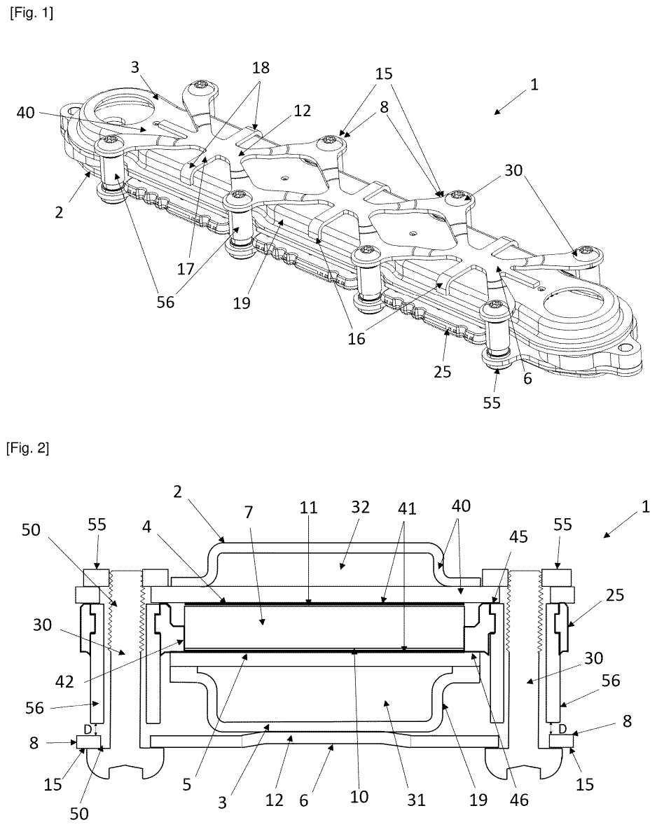

FIG. 1 shows an electronic assembly 1 according to the invention.

The electronic assembly 1 comprises:
a first cooling device 2 comprising a first thermal contact face 4,
a second cooling device 3 comprising a second thermal contact face 5 and a bearing face,
three power electronics modules 7 having a first face 10 and a second face 11, in particular parallel to one another, the first face 10 of the power electronics modules 7 being in thermal contact with the first thermal contact face 4 of the first cooling device 2 and the second face 11 of the power electronics modules being in thermal contact with the second thermal contact face 5 of the second cooling device 3,
a retention structure 6 placed in contact with the bearing face of the second cooling device 3, and comprising at least one elastic portion 8,
a plurality of attachment elements 30.

The retention structure 6 comprises a retention face 12 arranged to be placed in contact with the bearing face of the second cooling device 3.

The retention structure 6 comprises a plurality of elastic portions 8.

The retention structure 6 comprises a plurality of wings 15 forming elastic portions 8 of the retention structure 6, and extending from the retention face of the retention structure 6.

The wings 15 extend on either side of the second cooling device 3, and are not in contact with the second cooling device 3.

The retention structure 6 comprises a plurality of retention tabs 16 each comprising a flat portion 17 forming part of the retention face 12 of the retention structure 6, and a bent portion 18 arranged to come into contact with a lateral face 19 of the second cooling device 3 in such a way as to hold the second cooling device 3 in position laterally.

Lateral face 19 of the second cooling device 3 refers to the faces of the second cooling device 3 that are substantially perpendicular to the bearing face of the second cooling device 3.

The retention structure 6 comprises at least two retention tabs 16 placed in contact with opposite lateral faces 19 of the second cooling device 3.

The retention structure 6 is made of metal, notably aluminium.

The electronic assembly 1 comprises three power electronics modules 7, notably arranged in a row, and sandwiched between the first cooling device 2 and the second cooling device 3.

The electronic assembly 1 comprises a positioning support 25 arranged to receive the power electronics modules 7 and to allow relative positioning between the power electronics modules 7, the first cooling device 2 and the second cooling device 3 when the electronic assembly 1 is being put together.

FIG. 2 shows a view in cross section of an electronic assembly 1 according to the invention, before clamping of the attachment elements 30.

The first cooling device 2 comprises a first circulation channel 31 for a heat transfer fluid, and the second cooling device 3 comprises a second circulation channel 32 for a heat transfer fluid.

The first circulation channel 31 and the second circulation channel 32 for heat transfer fluid have a substantially rectangular section.

The power electronics modules 7 are sandwiched between the first cooling device 2 and the second cooling device 3.

Advantageously, the invention thus makes it possible to cool the power electronics module 7 on both faces, thus making it possible to discharge a greater amount of heat.

Advantageously, since the first cooling device 2 and the second cooling device 3 have heat transfer fluid circulating through them, they make it possible to discharge more efficiently the heat released by the power electronics module 7 when it is in operation.

The first cooling device 2 and the second cooling device 3 each comprise plates 40 configured to form at least one circulation channel for a heat transfer fluid, one of the plates 40 defining the first thermal contact face 4 and the second thermal contact face 5, respectively.

The first cooling device 2 and the second cooling device 3 have a similar structure, with a heat transfer fluid channel formed by plates 40.

The heat transfer fluid circulation channel of the first cooling device 2 and the second cooling device 3 have a generally rectilinear shape.

The first cooling device 2 and the second cooling device 3 are made of metal, for example aluminium.

According to one aspect of the invention, a thermal interface material 41 (for example a gap filler or thermal paste or thermal grease or a film) is present between the first face 10 of the power electronics module 7 and the first thermal contact face 4 of the first cooling device 2, and between the second face 11 of the power electronics module 7 and the second thermal contact face 5 of the second cooling device 3.

The positioning support 25 takes the form of a frame, and comprises a plurality of positioning openings 42, in particular as many positioning openings as there are power electronics modules, each positioning opening being arranged to accommodate a power electronics module 7.

In this instance, the positioning support 25 comprises three positioning openings.

The positioning support 25 comprises an upper face 45 and a lower face 46.

The upper face 45 of the positioning support 25 is placed in contact with the first cooling device 2, and comprises positioning reliefs making it possible to position the first cooling device 2 on the positioning support 25.

The lower face 46 of the positioning support 25 is placed in contact with the second cooling device 3, and comprises positioning reliefs making it possible to position the second cooling device 3 on the positioning support 25.

The positioning support 25 is sandwiched between the first cooling device 2 and the second cooling device 3, and forms a stack with the first cooling device 2 and the second cooling device 3.

The positioning support 25 is made of metal or plastic.

The attachment elements 30 are screws.

The attachment elements 30 exert a force on the retention structure 6, and exert an opposite force on the first cooling device 2.

The first cooling device 2 and the elastic portion 8 of the retention structure 6 each comprise a plurality of attachment holes 50.

According to an embodiment of the invention that has not been shown, the attachment elements 30 are attached directly to the first cooling device 2, and apply a force directly on the first cooling device 2.

For example, the attachment elements 30 are screws screwed directly into an attachment hole 50 in the first cooling device 2.

According to another embodiment of the invention, the attachment elements 30 are attached to intermediate parts 55 placed bearing on the second cooling device 3, and exerting the opposite force on the first cooling device 2.

For example, the attachment elements are screws 30 screwed onto nuts 55 placed bearing on the first cooling device 2.

The electronic assembly 1 comprises a plurality of adjustment rings 56.

The adjustment rings 56 have a tubular shape, and are placed around the attachment elements 30 of the electronic assembly 1.

The adjustment rings 56 comprise an upper face and a lower face.

The lower face of the adjustment rings 56 is placed in contact with a flat surface of the positioning support 25 and of the first cooling device, and the upper face of the adjustment rings 56 is parallel to the retention structure 6, and is placed facing an elastic area of the retention structure 6 such that:
when the retention structure 6 is placed, without deformation, in contact with the second cooling device 3, the upper face of the adjustment rings 56 is located at a distance D from the retention structure 6,
when the retention structure 6 is deformed by the force exerted by the screws, the elastic parts of the retention structure 6 are in contact with the upper face of the adjustment rings 56.

Advantageously, the height of the adjustment rings 56 makes it possible to adjust the distance D between the retention structure 6 and the upper face of the adjustment rings 56, and thus adjust the maximum deformation of the elastic parts of the retention structure 6.

Advantageously, the adjustment of the height of the adjustment rings 56 makes it possible to adjust the vertical loads generated on the bearing face of the second cooling device 3 by the retention structure 6.

The plurality of attachment elements 30 passes through the attachment holes 50 and exerts a force on the retention structure 6, causing deformation of the elastic portions 8 of the retention structure 6, this deformation giving rise to clamping loads on the bearing face of the second cooling device 3, these clamping loads being sufficient to rigidly secure together the first cooling device 2, the second cooling device 3 and the retention structure 6.

Advantageously, the invention makes it possible to reduce the distance between the cooling devices and the power electronics module 7.

Advantageously, the use of a retention structure 6 comprising an elastic portion 8 makes it possible to put together the electronic assembly 1 as an autonomous assembly, without the need for attachment to a support part.

This allows the electronic assembly 1 to be put together in one piece before it is attached to other components.

The electronic assembly 1 is notably configured to be integrated in an inverter.

1. Electronic assembly comprising:
a first cooling device comprising a first thermal contact face,
a second cooling device comprising a second thermal contact face and a bearing face,
at least one power electronics module having a first face and a second face, in particular parallel to one another, the first face of the power electronics module being in thermal contact with the first thermal contact face of the first cooling device and the second face of the power electronics module being in thermal contact with the second thermal contact face of the second cooling device,
a retention structure placed in contact with the bearing face of the second cooling device, and comprising at least one elastic portion,
a plurality of attachment elements,
wherein:
the first cooling device and the elastic portion of the retention structure each comprise a plurality of attachment holes,
the plurality of attachment elements passes through the attachment holes and exerts a force on the retention structure, causing deformation of the elastic portions of the retention structure, this deformation giving rise to clamping loads on the bearing face of the second cooling device, these clamping loads being sufficient to rigidly secure together the first cooling device, the second cooling device and the retention structure.

2. Electronic assembly according to claim 1, wherein the retention structure comprises a plurality of wings forming elastic portions of the retention structure, and extending from the retention face of the retention structure on either side of the second cooling device, without being in contact with the second cooling device.

3. Electronic assembly according to claim 1, wherein the retention structure comprises a plurality of retention tabs comprising a flat portion forming part of the retention face of the retention structure, and a bent portion arranged to come into contact with a lateral face of the second cooling device in such a way as to hold the second cooling device in position laterally.

4. Electronic assembly according to claim 1, wherein the retention structure is made of metal, notably aluminium.

5. Electronic assembly according to claim 1, wherein the first cooling device comprises a first circulation channel for a heat transfer fluid and/or wherein the second cooling device comprises a second circulation channel for a heat transfer fluid.

6. Electronic assembly according to claim 1, wherein a thermal interface material is present between the first face of the power electronics module and the first thermal contact face of the first cooling device and/or between the second face of the electronic module and the second thermal contact face of the second cooling device.

7. Electronic assembly according to claim 1, wherein the electronic assembly comprises a positioning support arranged to receive the power electronics module or modules and to allow relative positioning between the power electronics module, the first cooling device and the second cooling device when the electronic assembly is being put together.

8. Electronic assembly according to claim 1, comprising a plurality of adjustment rings comprising:
a lower face placed in contact with a flat surface of the positioning support and/or of the first cooling device,
an upper face parallel to the retention structure, and placed facing an elastic area of the retention structure such that:
when the retention structure is placed, without deformation, in contact with the second cooling device, the upper face of the adjustment rings is located at a distance D from the retention structure,
when the retention structure is deformed by the force exerted by the attachment elements, the elastic parts of the retention structure are in contact with the upper face of the adjustment rings.

9. Electronic assembly according to claim 8, wherein the adjustment of the height of the adjustment rings makes it possible to adjust the vertical loads generated on the bearing face of the second cooling device by the retention structure.

10. Inverter comprising an electronic assembly according to claim 1.

11. Electronic assembly according to claim 2, wherein the retention structure comprises a plurality of retention tabs comprising a flat portion forming part of the retention face of the retention structure, and a bent portion arranged to come into contact with a lateral face of the second cooling device in such a way as to hold the second cooling device in position laterally.

12. Electronic assembly according to claim 2, wherein the retention structure is made of metal, notably aluminium.

13. Electronic assembly according to claim 2, wherein the first cooling device comprises a first circulation channel for a heat transfer fluid and/or wherein the second cooling device comprises a second circulation channel for a heat transfer fluid.

14. Electronic assembly according to claim 2, wherein a thermal interface material is present between the first face of the power electronics module and the first thermal contact face of the first cooling device and/or between the second face of the electronic module and the second thermal contact face of the second cooling device.

15. Electronic assembly according to claim 2, wherein the electronic assembly comprises a positioning support arranged to receive the power electronics module or modules and to allow relative positioning between the power electronics module, the first cooling device and the second cooling device when the electronic assembly is being put together.

16. Electronic assembly according to claim 2, comprising a plurality of adjustment rings comprising:
a lower face placed in contact with a flat surface of the positioning support and/or of the first cooling device,
an upper face parallel to the retention structure, and placed facing an elastic area of the retention structure such that:
when the retention structure is placed, without deformation, in contact with the second cooling device, the upper face of the adjustment rings is located at a distance D from the retention structure,
when the retention structure is deformed by the force exerted by the attachment elements, the elastic parts of the retention structure are in contact with the upper face of the adjustment rings.

17. Inverter comprising an electronic assembly according to claim 2.

18. Electronic assembly according to claim 3, wherein the retention structure is made of metal, notably aluminium.

19. Electronic assembly according to claim 3, wherein the first cooling device comprises a first circulation channel for a heat transfer fluid and/or wherein the second cooling device comprises a second circulation channel for a heat transfer fluid.

20. Electronic assembly according to claim 3, wherein a thermal interface material is present between the first face of the power electronics module and the first thermal contact face of the first cooling device and/or between the second face of the electronic module and the second thermal contact face of the second cooling device.
